(19) United States
(12) Patent Application Publication
(10) Pub. No.: US 2025/0143135 A1
(43) Pub. Date: May 1, 2025

(54) DISPLAY DEVICE AND MANUFACTURING METHOD FOR DISPLAY DEVICE

(71) Applicant: Samsung Display Co., LTD., Yongin-si (KR)

(72) Inventor: Doo Hyun LEE, Yongin-si (KR)

(21) Appl. No.: 18/779,918

(22) Filed: Jul. 22, 2024

(30) Foreign Application Priority Data
Nov. 1, 2023 (KR) 10-2023-0149331

(51) Int. Cl. H10K 59/38; H10K 59/12; H10K 59/122

(52) U.S. Cl. CPC H10K 59/38; H10K 59/1201; H10K 59/122

(57) ABSTRACT

A display device includes a light-emitting element layer including light-emitting elements, a first insulating layer including an inorganic layer above the light-emitting element layer, a color conversion layer including a bank and a quantum dot above the first insulating layer, a low refractive layer above the color conversion layer, and a second insulating layer including an inorganic material above the low refractive layer.

### CROSS-REFERENCE TO RELATED APPLICATION

The present application claims priority to, and the benefit of, Korean patent application No. 10-2023-0149331, filed on Nov. 1, 2023, in the Korean Intellectual Property Office, the entire disclosure of which is incorporated herein by reference.

### BACKGROUND

### 1. Field

The present disclosure generally relates to a display device, and a manufacturing method for a display device.

### 2. Description of the Related Art

With the development of information technologies, the importance of a display device, which is a connection medium between a user and information, increases. Accordingly, display devices, such as a liquid crystal display device and an organic light-emitting display device, are increasingly used.

As demands for high-quality display devices increase, it may be desirable to improve the light emission efficiency of display devices. Also, it may be suitable to reduce or prevent the likelihood of a product defect caused by an impurity as a structure strong against external influence is implemented.

### SUMMARY

Embodiments provide a display device, and a manufacturing method for a display device, which can improve light emission efficiency.

Embodiments also provide a display device, and a manufacturing method for a display device, which can reduce a risk that a defect will occur in a product structure.

In accordance with an aspect of the present disclosure, there is provided a display device including a light-emitting element layer including light-emitting elements, a first insulating layer including an inorganic layer above the light-emitting element layer, a color conversion layer including a bank and a quantum dot above the first insulating layer, a low refractive layer above the color conversion layer, and a second insulating layer including an inorganic material above the low refractive layer.

The low refractive layer may include an organic material, and may have a refractive index that is less than a refractive index of the color conversion layer.

The color conversion layer and the low refractive layer may contact each other without any organic layer therebetween.

The first insulating layer and the color conversion layer may contact each other without any organic layer therebetween.

The light-emitting element layer may include first electrodes respectively corresponding to the light-emitting elements, light-emitting layers respectively above the first electrodes, and a second electrode above the light-emitting layers, and below the first insulating layer.

The display device may further include a monomer is between the quantum dot and the first insulating layer, wherein the quantum dot is in openings defined by the bank and respectively overlapping with pixel areas.

The display device may further include a third insulating layer including an inorganic material between the color conversion layer and the low refractive layer.

The low refractive layer may extend to inside a bank well area, wherein the bank well area is an opening defined by the bank and spaced apart from pixel areas in plan view.

The display device may further include a monomer between the quantum dot and the first insulating layer, and between the first insulating layer and a portion of the low refractive layer extending to inside the bank well area, wherein the quantum dot is in another opening defined by the bank and overlapping one of the pixel areas.

The display device may further include a third insulating layer including an inorganic material between the color conversion layer and the low refractive layer, and between the monomer and a portion of the low refractive layer extending to inside the bank well area.

The display device may further include a pixel circuit layer including a pixel circuit, a second electrode in the light-emitting element layer, and a power line connected to the pixel circuit and connected to the second electrode through a contact hole, wherein the light-emitting element layer is above the pixel circuit layer, and wherein the bank well area overlaps with the contact hole.

The display device may further include a color filter layer above the second insulating layer and including color filters.

The display device may further include an overcoat layer over the color filter layer and including an organic material.

The color conversion layer may include a first color conversion pattern including a first quantum dot for converting light from the light-emitting element layer into light of a first color, and a second color conversion pattern including a second quantum dot for converting light from the light-emitting element layer into light of a second color.

In accordance with another aspect of the present disclosure, there is provided a display device including a pixel circuit layer above a base layer, and including a pixel circuit, a light-emitting element layer above the pixel circuit layer, and including first electrodes respectively corresponding to light-emitting elements, light-emitting layers respectively above the first electrodes, and a second electrode above the light-emitting layers, an insulating layer above the light-emitting element layer, and including an inorganic material, a color conversion layer above the insulating layer, and including a color conversion portion including a bank and a quantum dot, and a low refractive layer above the color conversion layer, including an organic material, having a refractive index that is less than a refractive index of the color conversion layer, and contacting the color conversion layer.

In accordance with still another aspect of the present disclosure, there is provided a method for manufacturing a display device, the method including forming a light-emitting element layer including a light-emitting element above a base layer, forming a first insulating layer including an inorganic material above the light-emitting element layer, forming a color conversion layer above the first insulating layer, the color conversion layer including a bank, and a color conversion portion surrounded by the bank in plan view and having a quantum dot, forming, above the color conversion layer, a low refractive layer including an organic material, and having a refractive index that is less than a refractive index of the color conversion layer, and forming a second insulating layer including an inorganic material above the low refractive layer.

### BRIEF DESCRIPTION OF THE DRAWINGS

Embodiments will now be described more fully hereinafter with reference to the accompanying drawings. However, the embodiments may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a plan view illustrating a display device in accordance with one or more embodiments of the present disclosure.

FIG. 2 is a circuit diagram illustrating one or more embodiments of any one of sub-pixels included in the display device shown in FIG. 1.

FIG. 3 is an enlarged view illustrating area A shown in FIG. 1.

FIG. 4 is a sectional view taken along the line I-I′ shown in FIG. 3 in accordance with one or more embodiments of the display device.

FIG. 5 is a sectional view taken along the line II-II′ shown in FIG. 3 in accordance with one or more embodiments of the display device.

FIG. 6 is a sectional view taken along the line I-I′ shown in FIG. 3 in accordance with one or more other embodiments of the display device.

FIG. 7 is a sectional view taken along the line II-II′ shown in FIG. 3 in accordance with one or more other embodiments of the display device.

FIG. 8 is a sectional view taken along the line I-I′ shown in FIG. 3 in accordance with still one or more other embodiments of the display device.

FIG. 9 is a sectional view taken along the line II-II′ shown in FIG. 3 in accordance with still one or more other embodiments of the display device.

FIG. 10 is a flowchart illustrating a manufacturing method for a display device in accordance with one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be

exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is

referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The present disclosure generally relates to a display device and a manufacturing method for a display device. Hereinafter, a display device and a manufacturing method for a display device in accordance with one or more embodiments of the present disclosure will be described with reference to the accompanying drawings.

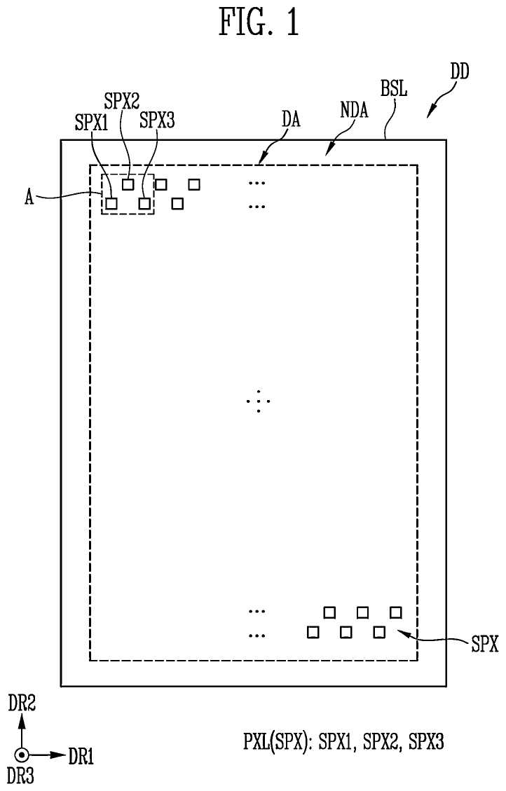

FIG. 1 is a plan view illustrating a display device in accordance with one or more embodiments of the present disclosure.

Referring to FIG. 1, the display device DD may include a base layer BSL, and sub-pixels SPX arranged on the base layer BSL. In one or more embodiments, the display device DD may further include a driving circuit (e.g., a scan driver and a data driver) for driving the sub-pixels SPX, lines, and pads.

The display device DD (or the base layer BSL) may include a display area DA and a non-display area NDA. The non-display area NDA may mean an area other than the display area DA. The non-display area NDA may surround at least a portion of the display area DA (e.g., in plan view).

The base layer BSL may form a base surface of the display device DD. The base layer BSL may be a rigid or flexible substrate or film. For example, the base layer BSL may be a rigid substrate made of glass or tempered glass, a flexible substrate (or thin film) made of a plastic or metal material, or at least one insulating layer. The material and/or property of the base layer BSL is not particularly limited. In one or more embodiments, the base layer BSL may be substantially transparent. The term “substantially transparent” may mean that light can be transmitted with a corresponding transmittance (e.g., predetermined transmittance) or more. In one or more other embodiments, the base layer BSL may be translucent or opaque. Also, the base layer

BSL may include a reflective material in some embodiments. In one or more embodiments, the base layer BSL may form a lower base.

The display area DA may mean an area in which the sub-pixels SPX are arranged. The non-display area NDA may mean an area in which the sub-pixels SPX are not located. The driving circuit, the lines, and the pads, which are connected to the sub-pixels SPX of the display area DA, may be located in the non-display area NDA.

The sub-pixels SPX may be arranged along a plurality of rows and a plurality of columns. For example, as shown in FIG. 1, a sub-pixel arranged on a second row and a first column may be defined as a first sub-pixel SPX1, a sub-pixel arranged on a first row and a second column may be defined as a second sub-pixel SPX2, and a sub-pixel arranged on the second row and a third column may be defined as a third sub-pixel SPX3.

In accordance with one or more embodiments, the sub-pixels SPX may be arranged according to a stripe arrangement structure, a PENTILE™ arrangement structure, or the like (e.g., a RGBG matrix structure, a PENTILE™ matrix structure, a PENTILE™ structure, or an RGBG structure, PENTILE™ being a registered trademark of Samsung Display Co., Ltd., Republic of Korea). However, the present disclosure is not limited thereto, and various embodiments may be applied in the present disclosure.

The first sub-pixel SPX1, the second sub-pixel SPX2, and the third sub-pixel SPX3 may constitute one pixel unit capable of emitting lights of various colors. For example, each of the first sub-pixel SPX1, the second sub-pixel SPX2, and the third sub-pixel SPX3 may emit light of one color. For example, the first sub-pixel SPX1 may be a red pixel for emitting light of red (e.g., a first color), the second sub-pixel SPX2 may be a green pixel for emitting light of green (e.g., a second color), and the third sub-pixel SPX3 may be a blue pixel for emitting light of blue (e.g., a third color). In accordance with one or more embodiments, a number of second sub-pixels SPX2 may be greater than a number of first sub-pixels SPXL1 and a number of third sub-pixels SPXL3. However, the color, kind, and/or number of first, second, and third sub-pixels SPX1, SPX2, and SPX3 constituting each pixel unit are not limited to a specific example.

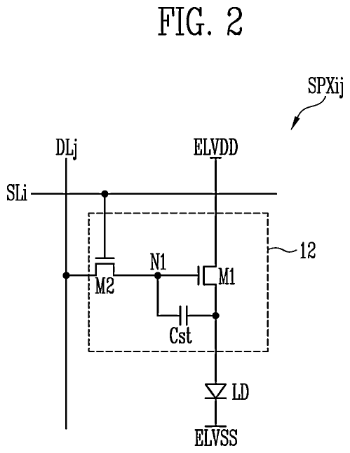

FIG. 2 is a circuit diagram illustrating one or more embodiments of any one of sub-pixels included in the display device shown in FIG. 1. In FIG. 2, for convenience of description, a sub-pixel SPXij located on an ith row and a jth column is illustrated.

Referring to FIG. 2, the sub-pixel SPXij may include a pixel circuit 12 connected to a scan line SLi and to a data line DLj, and a light-emitting element LD connected to the pixel circuit 12. In some embodiments, the light-emitting element LD may be selected as an organic light-emitting diode. Also, the light-emitting element LD may be selected as an inorganic light-emitting diode, such as a micro LED (light-emitting diode) or a quantum dot light-emitting diode. Also, the light-emitting element LD may be an element configured with a combination of an organic material and an inorganic material.

The pixel circuit 12 may include first and second transistors M1 and M2 and a storage capacitor Cst. In some embodiments, the first transistor M1 may include a drain electrode connected to a first power source ELVDD, a source electrode connected to a pixel electrode (e.g., to an anode electrode of the light-emitting element LD), and a gate electrode connected to a first node N1. In some embodiments, the drain electrode and the source electrode of the first transistor M1 may be electrically connected to each other according to a polarity of a voltage applied to the first transistor M1 and/or a type of the first transistor M1. The first transistor M1 may control a driving current flowing from the first power source ELVDD to a second power source ELVSS via the light-emitting element LD, and corresponding to a voltage of the first node N1. That is, the first transistor M1 may be a driving transistor for controlling a driving current of the sub-pixel SPXij. In some embodiments, the first power source ELVDD and the second power source ELVSS may be a high-potential pixel power source and a low-potential pixel power source, respectively.

In some embodiments, the second transistor M2 may include a drain electrode connected to the data line DLj, a source electrode connected to the first node N1, and a gate electrode connected to the scan line SLi. In some embodiments, the drain electrode and the source electrode of the second transistor T2 may be switched to each other according to a polarity of a voltage applied to the second transistor M2 and/or a type of the second transistor M2. The second transistor M2 may be turned on when a scan signal having a gate-on voltage (e.g., a high voltage) is supplied from the scan line SLi. When the second transistor M2 is turned on, the data line DLj and the first node N1 may be electrically connected to each other. That is, the second transistor M2 may be a switching transistor for controlling connection between the sub-pixel SPXij and the data line DLj.

In some embodiments, the storage capacitor Cst may be connected between one electrode (e.g., the source electrode of the first transistor M1) and the first node N1. The storage capacitor Cst may store a voltage corresponding to a data signal supplied to the first node N1, and may maintain the stored voltage during a period (e.g., predetermined period). For example, the storage capacitor Cst may maintain the stored voltage until a data signal of a next frame is supplied. Meanwhile, in some embodiments, the connection position of the storage capacitor Cst may be changed. For example, the storage capacitor Cst may be connected between the first power source ELVDD and the first node N1.

In some embodiments, the light-emitting element LD may be connected between the first transistor M1 and the second power source ELVSS. In an example, the light-emitting element LD may include the anode electrode connected to the source electrode of the first transistor M1, and a cathode electrode connected to the second power source ELVSS. The light-emitting element LD may emit light with a luminance corresponding to the driving current controlled by the first transistor M1.

In FIG. 2, one or more embodiments is disclosed, in which the first and second transistors M1 and M2 are implemented with an N-type transistor. However, the present disclosure is not limited thereto. That is, in some embodiments, the first transistor or the second transistor M1 or M2 may be implemented with a P-type transistor. In an example, the first and second transistors M1 and M2 may be implemented with the P-type transistor as shown in FIG. 2.

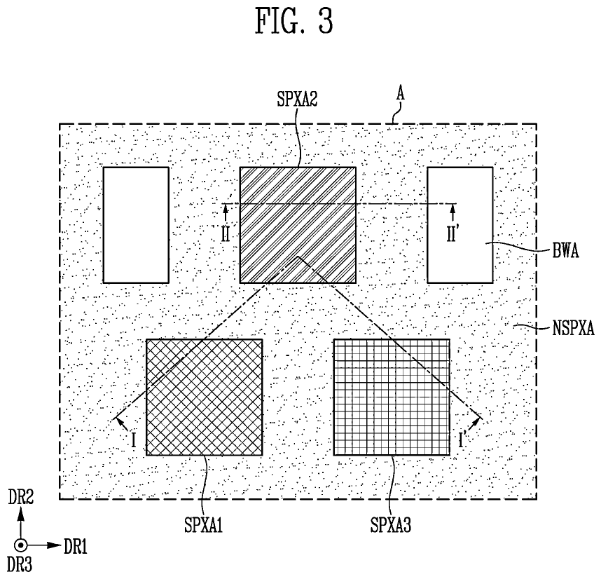

FIG. 3 is an enlarged view illustrating area A shown in FIG. 1.

Referring to FIG. 3, first to third sub-pixel areas SPXA1, SPXA2, and SPXA3, and a bank well area adjacent thereto, may be located in the area A. The first to third sub-pixel areas SPXA1, SPXA2, and SPXA3 shown in FIG. 3 may be repeatedly located in the entire display area DA (see FIG. 1). A peripheral area NSPXA may be located at the periphery of the first to third sub-pixel areas SPXA1, SPXA2, and SPXA3. The peripheral area NSPXA may set boundaries of the first to third sub-pixel areas SPXA1, SPXA2, and SPXA3. The peripheral area NSPXA may surround the first to third sub-pixel areas SPXA1, SPXA2, and SPXA3. A structure (e.g., a pixel-defining layer and/or a bank) for reducing or preventing a color mixture between the first to third sub-pixel areas SPXA1, SPXA2, and SPXA3 may be located in the peripheral area NSPXA.

The first to third sub-pixel areas SPXA1, SPXA2, and SPXA3 may correspond to the first to third sub-pixels SPX1, SPX2, and SPX3 shown in FIG. 1, respectively. The first to third sub-pixel areas SPXA1, SPXA2, and SPXA3 may be emission areas of the first to third sub-pixels SPX1, SPX2, and SPX3, respectively. For example, the pixel-defining layer and/or the bank, which define the first to third sub-pixel areas SPXA1, SPXA2, and SPXA3, may be located on the display area DA shown in FIG. 1, and corresponding light-emitting layers may be located in the first to third sub-pixel areas SPXA1, SPXA2, and SPXA3, respectively.

In FIG. 3, the first to third sub-pixel areas SPXA1, SPXA2, and SPXA3 which have the same shape on a plane and which have different areas on a plane are illustrated. However, the present disclosure is not limited thereto. Areas of at least two of the first to third sub-pixel areas SPXA1, SPXA2, or SPXA3 may be the same. The areas of the first to third sub-pixel areas SPXA1, SPXA2, and SPXA3 may be set according to a light emission color. The area of a sub-pixel area emitting light of red among primary colors may be the largest, and the area of a sub-pixel area emitting light of blue among the primary colors may be the smallest.

In FIG. 3, the first to third sub-pixel areas SPXA1, SPXA2, and SPXA3 having a rectangular shape are illustrated. However, the present disclosure is not limited thereto. On a plane, the first to third sub-pixel areas SPXA1, SPXA2, and SPXA3 may have another polygonal shape (including a substantial polygonal shape), such as a rhombic shape or a pentagonal shape. On a plane, the first to third sub-pixel areas SPXA1, SPXA2, and SPXA3 may have a rectangular shape (including a substantial rectangular shape) having round corner areas.

In FIG. 3, it is illustrated that the second sub-pixel area SPXA2 is arranged on the first row, and the first sub-pixel area SPXA1 and the third sub-pixel area SPXA3 are arranged on the second row. However, the present disclosure is not limited thereto, and the arrangement of the first to third sub-pixel areas SPXA1, SPXA2, and SPXA3 may be variously changed. For example, the first to third sub-pixel areas SPXA1, SPXA2, and SPXA3 may be arranged on the same row.

One of the first to third sub-pixel areas SPXA1, SPXA2, and SPXA3 may provide third color light corresponding to a source light, another of the first to third sub-pixel areas SPXA1, SPXA2, and SPXA3 may provide first color light that is different from the third color light, and the other of the first to third sub-pixel areas SPXA1, SPXA2, and SPXA3 may provide second color light that is different from both of the third color light and the first color light. The third sub-pixel area SPXA3 may provide the third color light. The first sub-pixel area SPXA1 may provide red light, the second sub-pixel area SPXA2 may provide green light, and the third sub-pixel area SPXA3 may provide blue light.

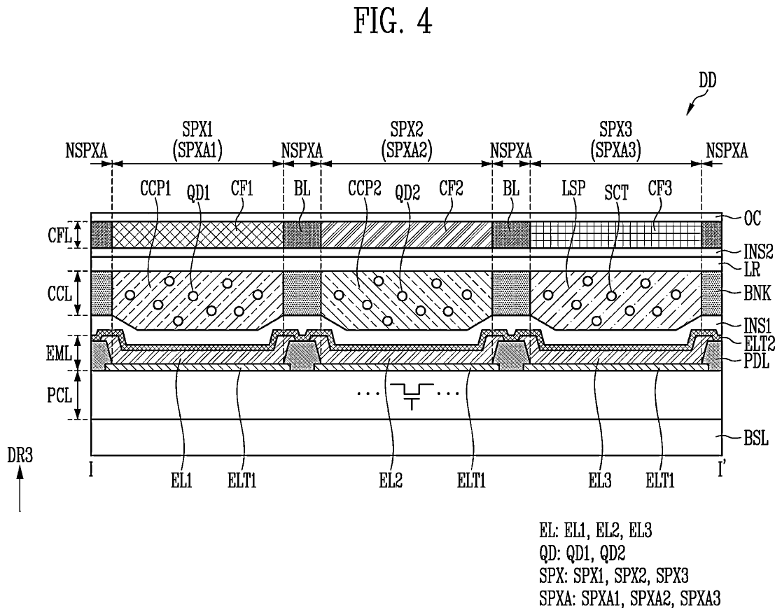

The bank well area BWA may be defined in the display area DA (see FIG. 1). The bank well area BWA may be an area for accommodating residues that may be formed in an unintended area in processes (e.g., a patterning process) of manufacturing a plurality of color conversion patterns CCP1 and CCP2 (see FIG. 4) and a light-scattering pattern LSP (see FIG. 4), which are included in a color conversion layer CCL (see FIG. 4). As the bank well area BWA is provided, unintended formation of residues in the color conversion layers CCL can be reduced, prevented, or minimized, and thus the likelihood of a corresponding defect of the display device can be reduced or prevented.

In FIG. 3, it is illustrated that two bank well areas BWA are defined to be adjacent to the second sub-pixel area SPXA2. However, the present disclosure is not limited thereto, and the number and/or arrangement of bank well areas BWA may be variously changed.

Next, sectional structures of display devices each including a color conversion layer in accordance with embodiments of the present disclosure will be described with reference to FIGS. 4 to 9. In FIGS. 4 to 9, portions overlapping with those described above will be briefly described or will not be repeated.

FIG. 4 is a sectional view taken along the line I-I′ shown in FIG. 3 in accordance with one or more embodiments of the display device.

Referring to FIG. 4, a display device DD may include a base layer BSL, a pixel circuit layer PCL, a light-emitting element layer EML, a first insulating layer INS1, a color conversion layer CCL, a low refractive layer LR, a second insulating layer INS2, a color filter layer CFL, and an overcoat layer OC.

The base layer BSL may include a rigid or flexible substrate or film. The base layer BSL may support the pixel circuit layer PCL, the light-emitting element layer EML, the first insulating layer INS1, the color conversion layer CCL, the low refractive layer LR, the second insulating layer INS2, the color filter layer CFL, and the overcoat layer OC.

The pixel circuit layer PCL may be located on the base layer BSL. The pixel circuit layer PCL may include a pixel circuit 12 (see FIG. 2) for driving a light-emitting element LD (see FIG. 2) of each sub-pixel. The pixel circuit layer PCL may include conductive layers for forming pixel circuits, and insulating layers located between the conductive layers.

The pixel circuit may include thin film transistors. For example, the pixel circuit may include a driving transistor. The pixel circuit may be electrically connected to the light-emitting element LD to provide an electrical signal for allowing the light-emitting element LD to emit light.

The light-emitting element layer EML may be located on the pixel circuit layer PCL. In some embodiments, the light-emitting element layer EML may include a first electrode ELT1, a pixel-defining layer PDL, each of first to third light-emitting layers EL1, EL2, and EL3, and a second electrode layer ELT2, which are located in each of first to third sub-pixel areas SPXA1, SPXA2, and SPXA3 (some, respectively). The first electrode ELT1 may be located in each of the first to third sub-pixel areas SPXA1, SPXA2, and SPXA3 on the pixel circuit layer PCL. The pixel-defining layer PDL may be located on the pixel circuit layer PCL, and may expose a portion of the first electrode ELT1 of each light-emitting element LD. A light-emitting layer EL may be located on the exposed portion of the first electrode ELT1. As such, the light-emitting layer EL may be located in an area defined by the pixel-defining layer PDL. One surface of the light-emitting layer EL may be electrically connected to the first electrode ELT1, and the other surface of the light-emitting layer EL may be electrically connected to the second electrode ELT2.

The first electrode ELT1 may be an anode electrode with respect to the light-emitting layer EL, and the second electrode ELT2 may be a common electrode (or a cathode electrode) with respect to the light-emitting layer EL. As such, a first electrode ELT1 located in each of the first to third sub-pixel areas SPXA1, SPXA2, and SPXA3, a light-emitting layer EL located in each of the first to third sub-pixel areas SPXA1, SPXA2, and SPXA3, and a portion of the second electrode ELT2, which overlaps with the corresponding light-emitting layer EL, may be provided as one light-emitting element LD.

In some embodiments, the first electrode ELT1 and the second electrode ELT2 may include a conductive material. For example, the first electrode ELT1 may include a conductive material having reflectivity, and the second electrode ELT2 may include a transparent conductive material. However, the present disclosure is not limited thereto.

The pixel-defining layer PDL may define the first to third pixel areas SPXA1, SPXA2, and SPXA3 respectively corresponding to first to third sub-pixels SPX1, SPX2, and SPX3. Sub-pixel areas SPXA may include the first sub-pixel area SPXA1 as an area formed by the first sub-pixel SPX1, in which light of a first color is emitted, the second sub-pixel area SPXA2 as an area formed by the second sub-pixel SPX2, in which light of a second color is emitted, and the third sub-pixel area SPXA3 as an area formed by the third sub-pixel SPX3, in which light of a third color is emitted.

In some embodiments, a light-emitting element LD of the first sub-pixel SPX1 may include the first light-emitting layer EL1. A light-emitting element LD of the second sub-pixel SPX2 may include the second light-emitting layer EL2. A light-emitting element LD of the third sub-pixel SPX3 may include the third light-emitting layer EL3.

In some embodiments, the first to third light-emitting layers EL1, EL2, and EL3 may emit light of the third color. However, the present disclosure is not necessarily limited thereto.

The light-emitting layer EL may have a multi-layer thin film structure including a light generation layer. The light-emitting layer EL may include a hole injection layer for injecting holes, a hole transport layer for increasing a hole recombination opportunity by suppressing movement of electrons, which are excellent in transportability of holes and are not combined in a light generation layer, the light generation layer for emitting light by recombination of the injected electrons and holes, a hole-blocking layer for suppressing the movement of the holes that are not combined in the light generation layer, an electron transport layer for smoothly transporting the electrons to the light generation layer, and an electron injection layer for injecting the electrons. The light-emitting layer EL may release light based on an electrical signal provided from the first electrode ELT1 and the second electrode ELT2.

The pixel-defining layer PDL may be located on the pixel circuit layer PCL, to define positions at which the light-emitting layers EL are arranged. The pixel-defining layer PDL may include an organic material. In some embodiments, the pixel-defining layer PDL may include acrylic resin, epoxy resin, phenolic resin, polyamide resin, and/or polyimide resin. However, the present disclosure is not limited thereto.

The first insulating layer INS1 may be located over the second electrode ELT2. The first insulating layer INS1 may include at least one insulating layer covering the first to third light-emitting layers EL1, EL2, and EL3 and/or the second electrode ELT2. The first insulating layer INS1 may be a capping layer for the first to third light-emitting layers EL1, EL2, and EL3 and/or the second electrode ELT2.

In some embodiments, the first insulating layer INS may be located over the second electrode ELT2 without any organic layer interposed therebetween. Experimentally, when an organic layer having a relatively thick thickness is located on the first to third light-emitting layers EL1, EL2, and EL3, light loss may occur in a process of allowing light provided from the first to third light-emitting layers EL1, EL2, and EL3 to be emitted to the outside. However, in some embodiments, the first insulating layer INS1 including an inorganic material may be located directly on the first to third light-emitting layers EL1, EL2, and EL3, and accordingly, a risk that light loss will occur can be resolved.

In some embodiments, the first insulating layer INS2 may include an inorganic material. The inorganic material may include silicon nitride (SiNₓ), silicon oxide (SiOₓ), silicon oxynitride (SiOₓN_{y}), and/or aluminum oxide (AlₓO_{y}). However, the present disclosure is not limited thereto.

The color conversion layer CCL may be located on the first insulating layer INS1. The color conversion layer CCL may include a bank BNK, color conversion patterns CCP1 and CCP2 including a quantum dot QD, and a light-scattering pattern LSP including a light-scattering particle SCT.

In one or more embodiments, the color conversion layer CCL may be located on the first insulating layer INS1 without any organic layer interposed therebetween. As the first to third light-emitting layers EL1, EL2, and EL3 and the quantum dot QD are configured such that a distance between the first to third light-emitting layers EL1, EL2, and EL3 and the quantum dot QD is relatively small, the light emission efficiency of light emitted from the first to third light-emitting layers EL1, EL2, and EL3 can be improved.

The bank BNK may be located on the first insulating layer INS1. The bank BNK may contact the first insulating layer INS1. The bank BNK may protrude in a thickness direction of the base layer BSL (e.g., a third direction DR3) from the first insulating layer INS1. The bank BNK may include an organic material. For example, the bank BNK may include acrylic resin, epoxy resin, phenolic resin, polyamide resin, and/or polyimide resin. However, the present disclosure is not limited thereto.

In one or more embodiments, the bank BNK may include openings. For example, the openings may be formed by etching the bank BNK. The openings may overlap with the first to third sub-pixel areas SPXA1, SPXA2, and SPXA3 or the bank well area.

The color conversion patterns CCL1 and CCL2 and the light-scattering pattern LSP, which respectively accord with colors of the first to third sub-pixel areas SPXA1, SPXA2, and SPXA3, may be located in the openings overlapping with the first to third sub-pixel areas SPXA1, SPXA2, and SPXA3. That is, the bank BNK may define the openings in which the color conversion patterns CCL1 and CCL2 and the light-scattering pattern LSP are located. As such, the bank BNK may define the first to third sub-pixel areas SPXA1, SPXA2, and SPXA3.

The color conversion patterns CCP1 and CCP2 may be configured to change the wavelength of light. The color conversion patterns CCP1 and CCP2 and the light-scattering pattern LSP may be located on the light-emitting element layer EML. The color conversion patterns CCP1 and CCP2 and the light-scattering pattern LSP may be below color filters CF1, CF2, and CF3. The color conversion patterns CCP1 and CCP2 and the light-scattering pattern LSP may be located between the color filter layer CFL and the light-emitting element layer EML. The color conversion patterns CCP1 and CCP2 and the light-scattering pattern LSP may be located (or patterned) in the openings surrounded by the bank BNK protruding in the thickness direction of the base layer BSL (e.g., the third direction DR3).

The first color conversion pattern CCL1 may include first color conversion particles for converting light of a third color (e.g., blue) emitted from a blue light-emitting layer into light of a first color (e.g., red).

For example, the first color conversion pattern CCL1 may include a plurality of first quantum dots QD1 dispersed in a matrix material, such as base resin. The first quantum dot QD1 may absorb blue light, and may emit red light by shifting a wavelength of the blue light according to energy transition.

The second color conversion pattern CCL2 may include second color conversion particles converting light of the third color (e.g., blue) emitted from the blue light-emitting layer into light of a second color (e.g., green).

For example, the second color conversion pattern CCL2 may include a plurality of second quantum dots QD2 dispersed in a matrix material, such as base resin. The second quantum dot QD2 may absorb blue light, and may emit green light by shifting a wavelength of the blue light according to energy transition.

In one or more embodiments, light of blue having a relatively short wavelength in a visible light band is incident into the first quantum dot QD1 and the second quantum dot QD2, so that absorption coefficients of the first quantum dot QD1 and the second quantum dot QD2 can be increased. Accordingly, the efficiency of light finally emitted from the first sub-pixel SPX1 and the second sub-pixel SPX2 can be improved, and excellent color reproduction can be ensured.

The light-scattering pattern LSL may be provided to efficiently use light of the third color (e.g., blue) emitted from the blue light-emitting layer. For example, the light-scattering pattern LSL may include the light-scattering particle SCT. In an example, the light-scattering particle SCT of the light-scattering pattern LSL may include various light-scattering particles and various light-scattering materials.

For example, the light-scattering particle SCT may include silica (SiOₓ) (e.g., silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and/or antimony oxide (SbₓO_{y}). However, the present disclosure is not limited thereto.

Meanwhile, the light-scattering particle SCT is not necessarily located in only the third sub-pixel SPX3, and may be selectively included in the first color conversion pattern CCL1 and/or the second color conversion pattern CCL2. In some embodiments, the light-scattering particle SCT may be omitted such that the light-scattering pattern LSL configured with transparent polymer is provided.

The low refractive layer LR may be located on the color conversion layer. In one or more embodiments, the low refractive layer LR and the color conversion layer CCL may contact each other without any organic layer located interposed therebetween. For example, the low refractive layer LR may be located on the bank BNK, the color conversion patterns CCP1 and CCP2, and the light-scattering pattern LSP.

The low refractive layer LR may function to improve light extraction efficiency by recycling light provided from the color conversion layer CCL through total reflection. To this end, the low refractive layer LR may have a refractive index that is less than a refractive index of the color conversion layer CCL. For example, the refractive index of the color conversion layer may be about 1.6 to about 2.0, and the refractive index of the low refractive layer LR may be about 1.1 to about 1.3.

The low refractive layer LR may have various materials to have one refractive index. For example, the low refractive layer LR may include an organic material. However, the present disclosure is not limited thereto.

The second insulating layer INS2 may be located over the low refractive layer LR. The second insulating layer INS2 may be provided throughout the first to third sub-pixels SPX1, SPX2, and SPX3. The second insulating layer INS2 may cover the low refractive layer LR. The second insulating layer INS2 may reduce or prevent the likelihood of the low refractive layer LR being damaged or contaminated due to infiltration of moisture, air, or the like from the outside.

The second insulating layer INS2 may include an inorganic material. The inorganic material may include silicon nitride (SiNₓ), silicon oxide (SiOₓ), silicon oxynitride (SiOₓN_{y}), and/or aluminum oxide (AlOₓ). However, the present disclosure is not limited thereto.

The color filter layer CFL may be located on the second insulating layer INS2. The color filter layer CFL may include a first color filter CF1, a second color filter CF2, and a third color filter CF3.

Each of the color filters CF1, CF2, and CF3 may allow light in a wavelength range corresponding to one color to be selectively transmitted therethrough. In accordance with one or more embodiments, the color filters CF1, CF2, and CF3, which respectively accord with colors of the respective first to third sub-pixels SPX1, SPX2, and SPX3, are arranged so that a full-color image can be displayed.

The first color filter CF1 is a color filter for forming the first sub-pixel SPX1, and may overlap with the first sub-pixel area SPXA1 when viewed on a plane (e.g., in plan view). The first color filter CF1 may allow light of a first color to be selectively transmitted therethrough. The first color filter CF1 may be a red color filter, and may include a red color filter material.

The second color filter CF2 is a color filter for forming the second sub-pixel SPX2, and may overlap with the second sub-pixel area SPXA2 when viewed on a plane. The second color filter CF2 may allow light of a second color to be selectively transmitted therethrough. The second color filter CF2 may be a green color filter, and may include a green color filter material.

The third color filter CF3 is a color filter for forming the third sub-pixel SPX3, and may overlap with the third sub-pixel area SPXA3 when viewed on a plane. The third color filter CF3 may allow light of a third color to be selectively transmitted therethrough. The third color filter CF3 may be a blue color filter, and may include a blue color filter material.

In some embodiments, two or more color filters among the first to third color filters CF1, CF2, and CF3 may overlap with each other in a peripheral area NSPXA when viewed on a plane, and color filters overlapping with each other may form a light-blocking layer BL in the peripheral area NSPXA. The light-blocking layer BL may be located between the sub-pixel areas SPXA. However, the present disclosure is not necessarily limited thereto. In some embodiments, a separate light-blocking material may be located between the sub-pixel areas SPXA to form the light-blocking layer BL.

The overcoat layer OC may be located over the color filter layer CFL. The overcoat layer OC may be a planarization layer, and may be a protective layer for protecting the inside of the display device from external influence. The overcoat layer OC may include an organic material. However, the present disclosure is not limited thereto.

In one or more embodiments, a film layer may be located on an overcoat layer OC. The film layer may include a polyethylene terephthalate (PET) film, a low reflective film, a polarizing film, and/or a transmittance controllable film. However, the present disclosure is not limited thereto.

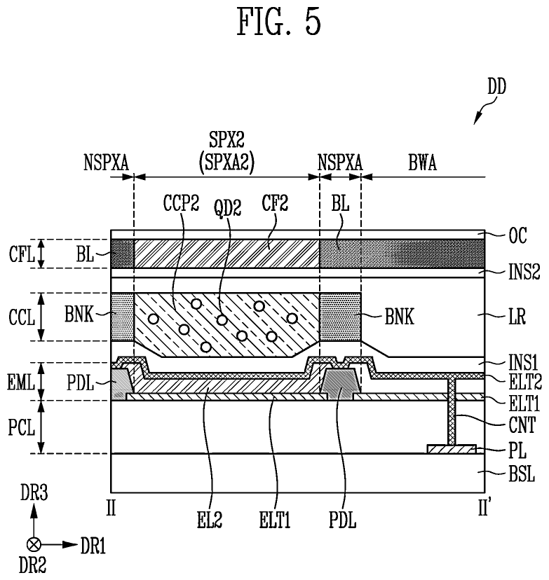

FIG. 5 is a sectional view taken along the line II-II′ shown in FIG. 3 in accordance with one or more embodiments of the display device.

Referring to FIG. 5, a display device DD may include a base layer BSL, a pixel circuit layer PCL, a light-emitting element layer EML, a first insulating layer INS1, a color conversion layer CCL, a low refractive layer LR, a second insulating layer INS2, a color filter layer CFL, and an overcoat layer OC. The display device DD shown in FIG. 5 may be described similarly to the display device DD shown in FIG. 4, and overlapping descriptions will be simplified or omitted.

Referring to FIGS. 4 and 5 together, the bank BNK may define a bank well area BWA spaced apart from the first to third sub-pixel areas SPXA1, SPXA2, and SPXA3 on a plane. That is, the bank well area BWA may be designated as an opening not overlapping with the first to third sub-pixel areas SPXA1, SPXA2, and SPXA3 on a plane among the openings of the bank BNK.

The bank well area BWA may be formed by removing a partial area of the bank BNK so as to reduce or prevent the likelihood of a corresponding defect in a process of patterning the color conversion patterns CCP1 and CCP2 and the light-scattering pattern LSP, which are included in the color conversion layer CCL.

The bank well area BWA is a portion into which a color conversion patterns CCP1 and CCP2 and the light-scattering pattern LSP forming material, which may be erroneously applied in the process of patterning the color conversion patterns CCP1 and CCP2 and the light-scattering pattern LSP, may flow. Through the bank well area BWA, there can be reduced or prevented the likelihood of the erroneously applied color conversion patterns CCP1 and CCP2 and the light-scattering pattern LSP forming material causing a defect in a process of forming an upper member as the color conversion patterns CCP1 and CCP2, and the light-scattering pattern LSP forming material remains on the top of the bank BNK. In one or more embodiments, a portion of an ink composition for forming the color conversion patterns CCP1 and CCP2 and the light-scattering pattern LSP may be located in at least a portion of the bank well area WBA.

In the bank well area BWA, the low refractive layer LR may extend to the inside of the bank well area BWA to be located on the first insulating layer INS1. In one or more embodiments, the inside of the bank well area BWA may be filled with the low refractive layer LR. That is, in the bank well area BWA, one surface of the low refractive layer LR may contact the first insulating layer INS1, and the other surface of the low refractive layer LR may contact the second insulating layer INS2.

In one or more embodiments, the low refractive layer LR may be located on the bank BNK, on the color conversion patterns CCP1 and CCP2, and on the light-scattering pattern LSP, and may be located to extend to the inside of the bank well area BWA. Accordingly, any excessive step differences between the color conversion patterns CCP1 and CCP2, the light-scattering pattern LSP, and the bank well area BWA do not occur.

The bank well area BWA may overlap with a contact hole CNT. The contact hole CNT may connect a power line PL located in the pixel circuit layer PCL to the second electrode ELT2 of the light-emitting element layer EML. The power line PL may provide the second power source ELVSS (see FIG. 2) to the pixel circuit 12 (see FIG. 2) of the pixel circuit layer PCL. In the bank well area BWA, any light-emitting layer may not be located. In one or more embodiments, a light-emitting layer located in the bank well area WBA may be removed in a manufacturing process.

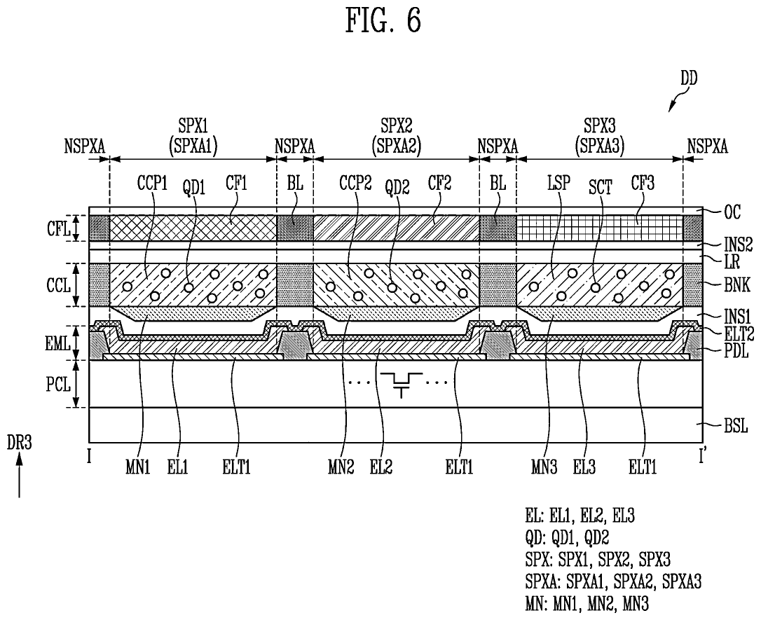

FIG. 6 is a sectional view taken along the line I-I′ shown in FIG. 3 in accordance with one or more other embodiments of the display device.

Referring to FIG. 6, a display device DD may include a base layer BSL, a pixel circuit layer PCL, a light-emitting element layer EML, a first insulating layer INS1, a color conversion layer CCL, a low refractive layer LR, a second insulating layer INS2, a color filter layer CFL, and an overcoat layer OC.

The display device DD shown in FIG. 6 may be described similarly to the display device DD shown in FIG. 4, and overlapping descriptions will be simplified or omitted.

The color conversion layer CCL may include a bank BNK, color conversion patterns CCP1 and CCP2 including a quantum dot QD, a light-scattering pattern LSP including a light-scattering particle SCT, and a monomer MN.

The monomer MN may be located between the first insulating layer INS1 and the color conversion patterns CCP1 and CCP2. For example, a first monomer MN1 may be located between the first insulating layer INS1 and a first color conversion pattern CCP1 in a first sub-pixel area SPXA1. A second monomer MN2 may be located between the first insulating layer INS1 and a second color conversion pattern CCP2 in a second sub-pixel area SPXA2.

Also, the monomer MN may be located between the first insulating layer INS1 and the light-scattering pattern LSP. A third monomer MN3 may be located between the first insulating layer INS1 and the light-scattering pattern LSP in a third sub-pixel area SPXA3.

In one or more embodiments, the monomer MN may be formed in the first insulating layer INS, and the color conversion patterns CCP1 and CCP2 or the light-scattering pattern LSP may be formed after the monomer MN is cured.

The monomer MN is located between the first insulating layer INS1 and the color conversion patterns CCP1 and CCP2, or is located between the first insulating layer INS1 and the light-scattering pattern LSP, so that moisture or oxygen can be reduced or prevented from infiltrating into the pixel circuit layer PCL and the light-emitting element layer EML during a manufacturing process of the display device DD.

Also, the monomer MN is located between the first insulating layer INS1 and the color conversion patterns CCP1 and CCP2, or is located between the first insulating layer INS1 and the light-scattering pattern LSP, so that a damage occurring at the surface of the color conversion patterns CCP1 and CCP2 or the light-scattering pattern LSP can be reduced by the first insulating layer INS1.

For example, the monomer MN may include lauryl acrylate, lauryl methacrylate, hydroxypropyl methacrylate, 3,5,5-trimethylhexyl acrylate, glycidyl methacrylate, tetrahydrofurfuryl acrylate, tetrahydrofurfuryl methacrylate, benzyl methacrylate, or cyclohexyl methacrylate. However, of the present disclosure is not limited thereto.

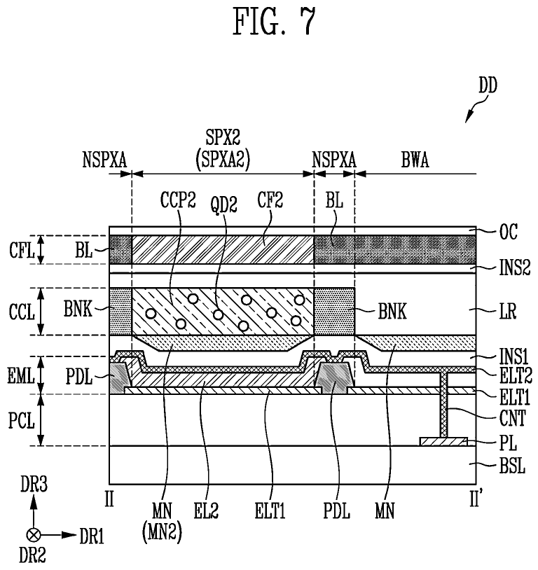

FIG. 7 is a sectional view taken along the line II-II′ shown in FIG. 3 in accordance with one or more other embodiments of the display device.

Referring to FIG. 7, a display device DD may include a base layer BSL, a pixel circuit layer PCL, a light-emitting element layer EML, a first insulating layer INS1, a color conversion layer CCL, a low refractive layer LR, a second insulating layer INS2, a color filter layer CFL, and an overcoat layer OC.

The display device DD shown in FIG. 7 may be described similarly to the display device DD shown in FIG. 5, and overlapping descriptions will be simplified or omitted. In addition, a monomer MN shown in FIG. 7 may be described similarly to the monomer MN shown in FIG. 6, and overlapping descriptions will be simplified or omitted.

In a bank well area BWA, a low refractive layer LR may extend to the inside of the bank well area BWA to be located on/above the first insulating layer INS1. The monomer MN may be located between a portion of the low refractive layer LR extending to the inside of the bank well area BWA and the first insulating layer INS1., In the bank well area BWA, the monomer MN may be contact with the first insulating layer INS1 and a portion of the low refractive layer LR directly.

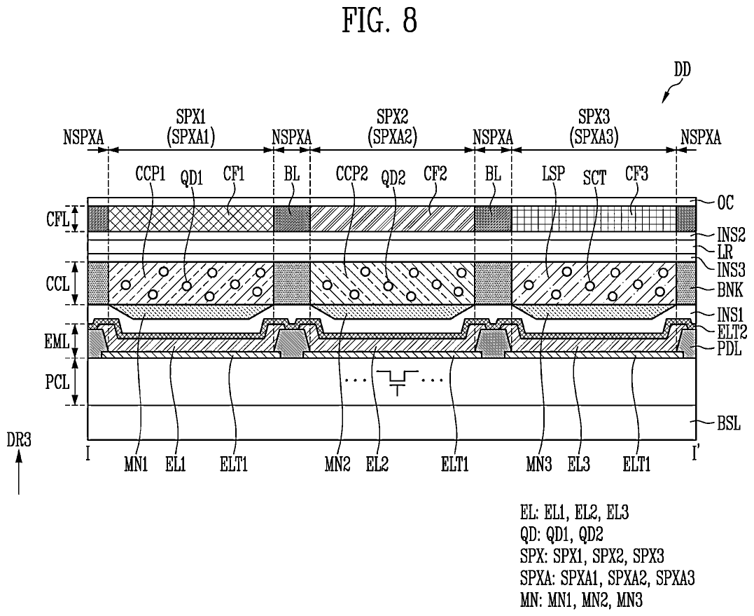

FIG. 8 is a sectional view taken along the line I-I′ shown in FIG. 3 in accordance with still one or more other embodiments of the display device.

Referring to FIG. 8, a display device DD may include a base layer BSL, a pixel circuit layer PCL, a light-emitting element layer EML, a first insulating layer INS1, a color conversion layer CCL, a third insulating layer INS3, a low refractive layer LR, a second insulating layer INS2, a color filter layer CFL, and an overcoat layer OC.

The display device DD shown in FIG. 8 may be described similarly to the display device DD shown in FIG. 6, and overlapping descriptions will be simplified or omitted.

The display device DD may further include the third insulating layer INS3 located between the color conversion layer CCL and the low refractive layer LR. In one or more embodiments, one surface of the third insulating layer INS3 may contact the color conversion layer CCL, and the other surface of the third insulating layer INS3 may contact the low refractive layer LR. Thus, the third insulating layer INS3 may be contact with the color conversion layer CCL and the low refractive layer LR directly.

The third insulating layer INS3 may include an inorganic material. The inorganic material may include silicon nitride (SiNₓ), silicon oxide (SiOₓ), silicon oxynitride (SiOₓN_{y}), and/or aluminum oxide (AlₓO_{y}). However, the present disclosure is not limited thereto.

The third insulating layer INS3 is located between the color conversion layer CCL and the low refractive layer LR, so that moisture or oxygen can be reduced or prevented from infiltrating into the color conversion layer CCL.

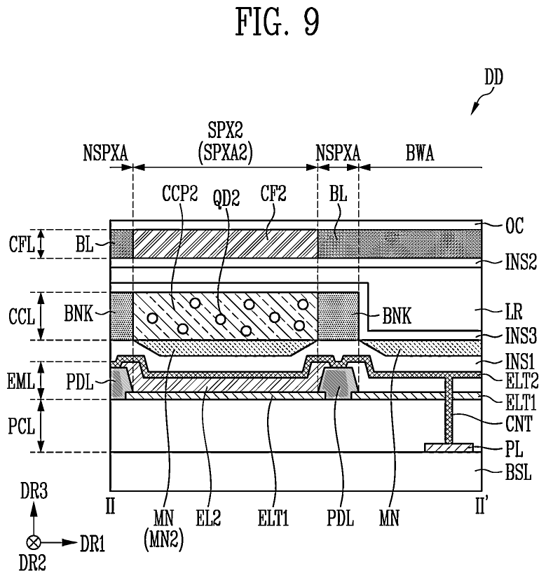

FIG. 9 is a sectional view taken along the line II-II′ shown in FIG. 3 in accordance with still one or more other embodiments of the display device.

Referring to FIG. 9, a display device DD may include a base layer BSL, a pixel circuit layer PCL, a light-emitting element layer EML, a first insulating layer INS1, a color conversion layer CCL, a third insulating layer INS3, a low refractive layer LR, a second insulating layer INS2, a color filter layer CFL, and an overcoat layer OC. FIG. 9 illustrates a section corresponding to the line II-II′ shown in FIG. 3.

The display device DD shown in FIG. 9 may be described similarly to the display device DD shown in FIG. 7, and overlapping descriptions will be simplified or omitted. In addition, the third insulating layer INS3 shown in FIG. 9 may be described similarly to the third insulating layer shown in FIG. 8, and overlapping descriptions will be simplified or omitted.

In a bank well area BWA, the third insulating layer INS3 may be located over a monomer MN. The low refractive layer LR may be located on the third insulating layer INS3. That is, the third insulating layer INS3 may extend to the inside of the bank well area BWA to be between a portion of the low refractive layer LR, which extends to the inside of the bank well area BWA, and the monomer MN. That is, in the bank well area BWA, one surface of the third insulating layer INS3 may contact the monomer, and the other surface of the third insulating layer INS3 may contact the low refractive layer LR. Thus, in the bank well area BWA, the third insulating layer INS3 may be contact with the monomer MN and the portion of the low refractive layer LR directly.

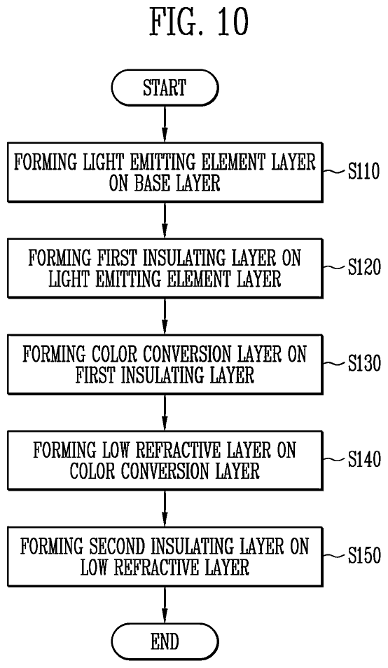

FIG. 10 is a flowchart illustrating a manufacturing method for a display device in accordance with one or more embodiments of the present disclosure.

Referring to FIGS. 4 and 10, in operation S110, a light-emitting element layer EML may be formed on a base layer BSL.

In operation S120, a first insulating layer INS1 may be formed on the light-emitting element layer EML. The first insulating layer INS1 may include an inorganic material.

In operation S130, a color conversion layer CCL may be formed on the first insulating layer INS1. In one or more embodiments, the color conversion layer CCL may be formed on the first insulating layer INS1 without forming any separate organic layer.

In operation S140, a low refractive layer LR may be formed on the color conversion layer CCL. The low refractive layer LR may have a refractive index that is less than a refractive index of the color conversion layer CCL. The low refractive layer LR may include an organic material. In one or more embodiments, the low refractive layer LR may be formed on the color conversion layer CCL without forming any separate organic layer.

In operation S150, a second insulating layer INS2 may be formed over the low refractive layer LR. The second insulating layer INS2 may include an inorganic material.

In accordance with the present disclosure, there can be provided a display device, and a manufacturing method for a display device, which can improve light emission efficiency.

In accordance with the present disclosure, there can be provided a display device and a manufacturing method for a display device, which can reduce a risk that a defect will occur in a product structure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a given embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims, with functional equivalents thereof to be included therein.

What is claimed is:

1. A display device comprising:
a light-emitting element layer comprising light-emitting elements;
a first insulating layer comprising an inorganic layer above the light-emitting element layer;
a color conversion layer comprising a bank and a quantum dot above the first insulating layer;
a low refractive layer above the color conversion layer; and
a second insulating layer comprising an inorganic material above the low refractive layer.

2. The display device of claim 1, wherein the low refractive layer comprises an organic material, and has a refractive index that is less than a refractive index of the color conversion layer.

3. The display device of claim 1, wherein the color conversion layer and the low refractive layer contact each other without any organic layer therebetween.

4. The display device of claim 1, wherein the first insulating layer and the color conversion layer contact each other without any organic layer therebetween.

5. The display device of claim 1, wherein the light-emitting element layer comprises:
first electrodes respectively corresponding to the light-emitting elements;
light-emitting layers respectively above the first electrodes; and
a second electrode above the light-emitting layers, and below the first insulating layer.

6. The display device of claim 1, further comprising a monomer is between the quantum dot and the first insulating layer,
wherein the quantum dot is in openings defined by the bank and respectively overlapping with pixel areas.

7. The display device of claim 6, further comprising a third insulating layer comprising an inorganic material between the color conversion layer and the low refractive layer and
wherein the third insulating layer contact with the color conversion layer and the low refractive layer directly.

8. The display device of claim 1, wherein the low refractive layer extends to inside a bank well area, and
wherein the bank well area is an opening defined by the bank and spaced apart from pixel areas in plan view.

9. The display device of claim 8, further comprising a monomer between the quantum dot and the first insulating layer, and between the first insulating layer and a portion of the low refractive layer extending to inside the bank well area,
wherein the quantum dot is in another opening defined by the bank and overlapping one of the pixel areas, and
wherein the monomer contacts with the first insulating layer and the portion of the low refractive layer directly.

10. The display device of claim 9, further comprising a third insulating layer comprising an inorganic material between the color conversion layer and the low refractive layer, and between the monomer and the portion of the low refractive layer extending to inside the bank well area, and
the third insulating layer contacts with the monomer and the portion of the low refractive layer directly.

11. The display device of claim 8, further comprising:
a pixel circuit layer comprising a pixel circuit;
a second electrode in the light-emitting element layer; and
a power line connected to the pixel circuit and connected to the second electrode through a contact hole,
wherein the light-emitting element layer is above the pixel circuit layer, and
wherein the bank well area overlaps with the contact hole.

12. The display device of claim 1, further comprising a color filter layer above the second insulating layer and comprising color filters.

13. The display device of claim 12, further comprising an overcoat layer over the color filter layer and comprising an organic material.

14. The display device of claim 1, wherein the color conversion layer comprises:
a first color conversion pattern comprising a first quantum dot for converting light from the light-emitting element layer into light of a first color; and
a second color conversion pattern comprising a second quantum dot for converting light from the light-emitting element layer into light of a second color.

15. A display device comprising:
a pixel circuit layer above a base layer, and comprising a pixel circuit;
a light-emitting element layer above the pixel circuit layer, and comprising first electrodes respectively corresponding to light-emitting elements, light-emitting layers respectively above the first electrodes, and a second electrode above the light-emitting layers;
an insulating layer above the light-emitting element layer, and comprising an inorganic material;
a color conversion layer above the insulating layer, and comprising a color conversion portion comprising a bank and a quantum dot; and
a low refractive layer above the color conversion layer, comprising an organic material, having a refractive index that is less than a refractive index of the color conversion layer, and contacting the color conversion layer.

16. A method for manufacturing a display device, the method comprising:
forming a light-emitting element layer comprising a light-emitting element above a base layer;
forming a first insulating layer comprising an inorganic material above the light-emitting element layer;
forming a color conversion layer above the first insulating layer, the color conversion layer comprising a bank, and a color conversion portion surrounded by the bank in plan view and having a quantum dot;
forming, above the color conversion layer, a low refractive layer comprising an organic material, and having a refractive index that is less than a refractive index of the color conversion layer; and
forming a second insulating layer comprising an inorganic material above the low refractive layer.
